(19) United States
(12) Patent Application Publication
(10) Pub. No.: US 2025/0180414 A1
(43) Pub. Date: Jun. 5, 2025

(54) LOAD SENSOR AND METHOD FOR MANUFACTURING LOAD SENSOR

(71) Applicant: Murata Manufacturing Co., Ltd., Nagaokakyo-shi (JP)

(72) Inventor: Yuuichi MUROZAKI, Nagaokakyo-shi (JP)

(21) Appl. No.: 19/048,070

(22) Filed: Feb. 7, 2025

Related U.S. Application Data
(63) Continuation of application No. PCT/JP2023/031038, filed on Aug. 28, 2023.

(30) Foreign Application Priority Data
Sep. 29, 2022 (JP) 2022-156312

(51) Int. Cl. G01L 1/16; H03H 3/02; H03H 9/10; H03H 9/19

(52) U.S. Cl. CPC G01L 1/162; H03H 3/02; H03H 9/105; H03H 9/19

(57) ABSTRACT

A load sensor that includes: an upper housing having an upper face portion, and a lateral face portion that extends in the thickness direction from an outer periphery of the upper face portion; a lower housing having a lower face portion that faces the upper face portion in the thickness direction, the lower housing being less elastically deformable than the upper housing; and a piezoelectric resonator in a space between the upper housing and the lower housing, wherein an end portion of the upper housing and an end portion of the lower housing are fixed to each other with a crimp such that the upper housing is elastically deformed and causes a preload to be applied by the upper housing to the piezoelectric resonator in the thickness direction.

### CROSS REFERENCE TO RELATED APPLICATIONS

The present application is a continuation of International application No. PCT/JP2023/031038, filed Aug. 28, 2023, which claims priority to Japanese Patent Application No. 2022-156312, filed Sep. 29, 2022, the entire contents of each of which are incorporated herein by reference.

### TECHNICAL FIELD

The present disclosure relates to a load sensor, and a method for manufacturing a load sensor.

### BACKGROUND ART

Load sensors utilizing a piezoelectric resonator are known. In such a load sensor, application of a load to a piezoelectric resonator causes the resonant frequency of the piezoelectric resonator to change in accordance with the applied load. The load sensor measures the magnitude of the load based on the change in resonant frequency.

Patent Document 1: Japanese Unexamined Patent Application Publication No. 2015-25796

For example, Patent Document 1 discloses a load sensor with a crystal resonator serving as a piezoelectric resonator. In the load sensor, fastening of a screw member causes a preload to be applied in the longitudinal direction to the crystal resonator via a holder housed within a case, and a thrust bearing serves to mitigate the torsional force that is exerted upon the preload application.

### SUMMARY OF THE DISCLOSURE

However, the preload application through fastening of a screw member as described in Patent Document 1 may lead to, for example, breakage of a crystal resonator element due to excessive preloading, or poor detection performance due to changes in preload when measurement is performed over an extended period of time. Further, the incorporation of the thrust bearing may make it impossible to achieve a reduction in the profile of the load sensor.

The present disclosure has been made in view of the circumstances mentioned above. Accordingly, it is an object of the present disclosure to provide a load sensor, and a method for manufacturing a load sensor that allow for a reduced profile of the load sensor, and reduced long-term fluctuations.

An aspect of the present disclosure relates to a load sensor that detects a load applied in a thickness direction. The load sensor includes: an upper housing having an upper face portion, and a lateral face portion that extends in the thickness direction from an outer periphery of the upper face portion; a lower housing having a lower face portion that faces the upper face portion in the thickness direction, the lower housing being less elastically deformable than the upper housing; and a piezoelectric resonator housed in a space between the upper housing and the lower housing, the piezoelectric resonator including a piezoelectric substrate between the upper face portion and the lower face portion, and a pair of excitation electrodes on opposite major faces of the piezoelectric substrate, wherein the pair of excitation electrodes extend in the thickness direction, and wherein an end portion of the upper housing and an end portion of the lower housing are fixed to each other with a crimp such that the upper housing is elastically deformed and causes a preload to be applied by the upper housing to the piezoelectric resonator in the thickness direction.

Another aspect of the present disclosure relates to a method for manufacturing a load sensor that detects a load in a thickness direction. The method including: setting a piezoelectric resonator above a lower housing having a lower face portion, the piezoelectric resonator including a piezoelectric substrate, and a pair of excitation electrodes on opposite major faces of the piezoelectric substrate; setting an upper housing on the piezoelectric resonator so as to cause the upper housing to be supported on the piezoelectric resonator and provide a preload adjustment gap between an end portion of the upper housing and an end portion of the lower housing, the upper housing having an upper face portion that faces the lower face portion in the thickness direction, and a lateral face portion that extends in the thickness direction from an outer periphery of the upper face portion, and the lower housing being less elastically deformable than the upper housing; and crimping the end portion of the upper housing and the end portion of the lower housing to each other while decreasing the preload adjustment gap and causing the upper housing to undergo elastic deformation and apply a preload to the piezoelectric resonator in the thickness direction.

The present disclosure can provide a load sensor, and a method for manufacturing a load sensor that allow for a reduced profile of the load sensor, and reduced long-term fluctuations.

### BRIEF DESCRIPTION OF THE DRAWINGS

FIG. 1 is a schematic perspective view of a load sensor according to a first embodiment.

FIG. 2 is a cross-sectional view of the load sensor according to the first embodiment, schematically illustrating the configuration of the load sensor.

FIG. 3 is an exploded perspective view of a piezoelectric resonator according to the first embodiment, schematically illustrating the structure of the piezoelectric resonator.

FIG. 4 illustrates the loading characteristics of the load sensor according to the first embodiment.

FIG. 5 is a flowchart illustrating a method for manufacturing the load sensor according to the first embodiment.

FIG. 6 is a cross-sectional view of the load sensor according to the first embodiment, illustrating the method for manufacturing the load sensor.

FIG. 7 is a cross-sectional view of a load sensor according to a second embodiment, schematically illustrating the structure of the load sensor.

FIG. 8 is a perspective view of the load sensor according to the second embodiment, schematically illustrating the structure of the load sensor.

FIG. 9 is a cross-sectional view of a load sensor according to a third embodiment, schematically illustrating the structure of the load sensor.

### DESCRIPTION OF THE PREFERRED EMBODIMENTS

Embodiments of the present disclosure will now be described with reference to the drawings. The drawings of the embodiments are illustrative only, and the illustrated dimensions, shapes, or other features of individual components or parts are schematic and not to be construed as limiting the technical scope of the present disclosure to the embodiments.

### First Embodiment

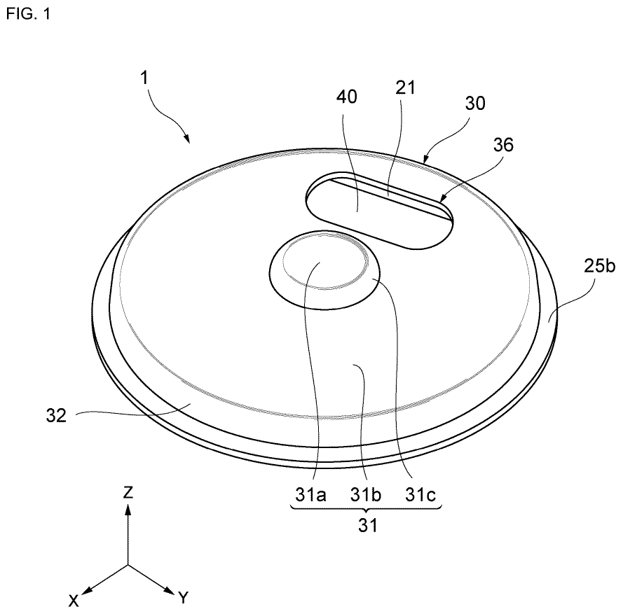

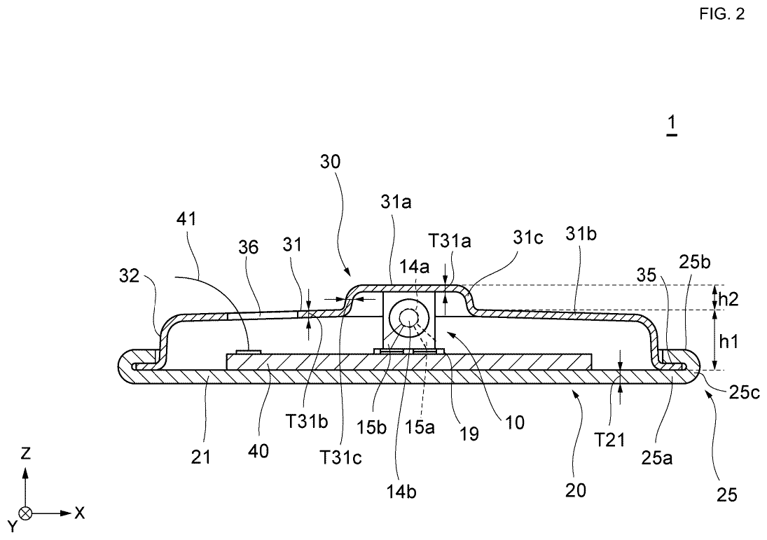

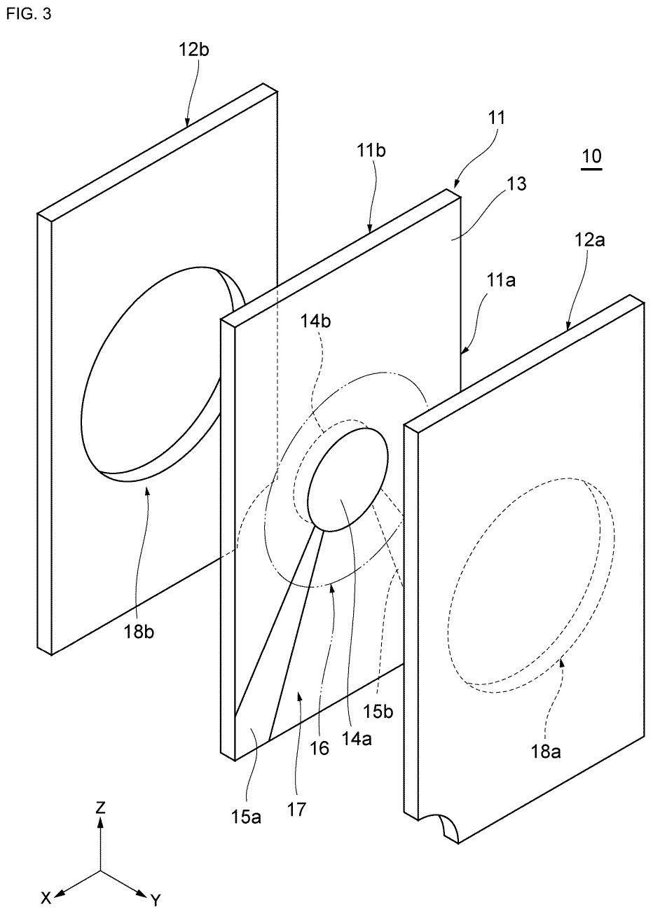

The configuration of a load sensor 1 according to a first embodiment of the present disclosure is described below with reference to FIGS. 1, 2, and 3. FIG. 1 is a schematic perspective view of the load sensor according to the first embodiment. FIG. 2 is a cross-sectional view of the load sensor according to the first embodiment, schematically illustrating the configuration of the load sensor. FIG. 3 is an exploded perspective view of the piezoelectric resonator according to the first embodiment, schematically illustrating the structure of the load sensor.

Individual figures are represented for convenience by an orthogonal coordinate system including an X-axis, a Y-axis, and a Z-axis to aid in clarifying the relationship between the figures and in understanding the relative positions of individual components or parts. A direction parallel to the X-axis, a direction parallel to the Y-axis, and a direction parallel to the Z-axis are respectively referred to herein as X-axis direction, Y-axis direction, and Z-axis direction. For convenience, a positive Z-axis direction (the direction pointed by the Z-axis arrow) is referred to as being “upper” or “upward”, and a negative Z-axis direction (direction opposite to the direction pointed by the Z-axis arrow) is referred to as being “lower” or “downward.” A plane defined by the X-axis and the Y-axis is referred to as X-Y plane, and the same applies to a Y-Z plane and a Z-X plane.

As illustrated in FIGS. 1 and 2, the load sensor 1 includes a piezoelectric resonator 10, a lower housing 20, an upper housing 30, and a buffer 40. The load sensor 1 detects a load applied in the thickness direction.

In the following description, a side of the load sensor 1 where the upper housing 30 exists is referred to as upper or upward (or front), and a side where the lower housing 20 exists is referred to as lower or downward (or back). The thickness direction of the load sensor 1, which is the direction of load detection, is also defined as the up-down direction as defined above.

The piezoelectric resonator 10 includes a piezoelectric resonator element 11, which is excited in accordance with applied voltage. In one non-limiting example, the piezoelectric resonator element 11 is a crystal resonator element utilizing a crystal blank as a piezoelectric body that vibrates in accordance with applied voltage.

The piezoelectric resonator 10 includes the piezoelectric resonator element 11, and a pair of holding layers 12a and 12b. As illustrated in FIG. 3, the piezoelectric resonator element 11 is clamped in the Y-axis direction between the holding layers 12a and 12b.

The piezoelectric resonator element 11 includes a piezoelectric substrate 13, a first excitation electrode 14a, a second excitation electrode 14b, a first connection electrode 15a, and a second connection electrode 15b. The piezoelectric resonator element 11 also includes a first major face 11a, and a second major face 11b. The first major face 11a and the second major face 11b extend in the X-Z plane, and are positioned opposite from each other with the piezoelectric resonator element 11 therebetween in the Y-axis direction. The first major face 11a defines the positive Y-axis side of the piezoelectric resonator element 11, and the second major face 11b defines the negative Y-axis side of the piezoelectric resonator element 11. The piezoelectric resonator element 11 includes a vibration portion 16, and a peripheral edge portion 17. The vibration portion 16 is located in the central part of the piezoelectric resonator element 11 in plan view of the X-Z plane, and contributes to excitation. The peripheral edge portion 17 surrounds the vibration portion 16. Although the vibration portion 16 has a circular shape in plan view of the X-Z plane, the shape of the vibration portion 16 is not limited to a circular shape. In plan view of the X-Z plane, the vibration portion 16 may have any shape including the first excitation electrode 14a and the second excitation electrode 14b. Such a shape may be, for example, a polygonal shape, an elliptical shape, or a combination thereof. The peripheral edge portion 17 is in the shape of a frame that extends continuously in the circumferential direction around the vibration portion 16. The shape of the peripheral edge portion, however, is not limited to the above-mentioned shape. Alternatively, the peripheral edge portion may be non-continuous in the circumferential direction.

The piezoelectric substrate 13 is a substrate having the shape of a flat plate and made of a piezoelectric body. The piezoelectric substrate 13 has a pair of major faces extending in the X-Z plane. The pair of major faces constitute the first major face 11a and the second major face 11b of the piezoelectric resonator element 11. The pair of major faces of the piezoelectric substrate 13 are in the shape of a rectangle with a short side extending in the X-axis direction and a long side extending in the Z-axis direction. The thickness direction, which is the direction of load detection, is aligned with the longitudinal direction of the piezoelectric substrate 13. This configuration allows the vibration portion 16 to exhibit increased distortion upon receiving a load applied in the thickness direction. This in turn leads to improved detection accuracy of the load sensor 1. The shape or orientation of the piezoelectric substrate 13 is not limited to that mentioned above, as long as the piezoelectric substrate 13 is capable of receiving a load. For example, the pair of major faces of the piezoelectric substrate may have a square shape, or may have a rectangular shape with a short side extending in the Z-axis direction. The pair of major faces of the piezoelectric substrate 13 may have a circular shape, an elliptical shape, a polygonal shape, or a combination of these shapes. Although the piezoelectric substrate is in the shape of a flat plate, this is not intended to be limiting. Alternatively, for example, the piezoelectric substrate may have a mesa shape, an inverted mesa shape, a beveled shape, or a convex shape.

The first excitation electrode 14a and the second excitation electrode 14b are disposed inside the vibration portion 16 in plan view of the X-Z plane, and stacked so as to clamp the piezoelectric substrate 13 in the Y-axis direction. The first excitation electrode 14a is disposed at the first major face 11a. Likewise, the second excitation electrode 14b is disposed at the second major face 11b in such a way that the second excitation electrode 14b is positioned to face the first excitation electrode 14a. In plan view of the X-Z plane, the first excitation electrode 14a and the second excitation electrode 14b are disposed inside the vibration portion 16, and spaced apart from the peripheral edge portion 17. The first excitation electrode 14a and the second excitation electrode 14b have a circular shape in plan view of the first major face 11a and the second major face 11b, respectively. It is to be noted, however, that the first excitation electrode 14a and the second excitation electrode 14b do not necessarily need to have the above-mentioned shape in plan view. Alternatively, the first excitation electrode 14a and the second excitation electrode 14b may have, in plan view, a polygonal shape, an elliptical shape, or a combination of these shapes, such as a rectangular shape.

The first connection electrode 15a extends from the first excitation electrode 14a to a corner portion of the piezoelectric resonator element 11 in the positive X-axis direction and the negative Z-axis direction, and is electrically connected to an external location outside of the piezoelectric resonator 10. Specifically, one end portion of the first connection electrode 15a is connected to the first excitation electrode 14a, and the other end portion is connected to the corner portion of the piezoelectric resonator element 11. The corner portion is exposed from the holding layer 12a. The first excitation electrode 14a is electrically connected to an external location via the first connection electrode 15a located in the area where the corner portion is exposed. Similarly to the first connection electrode 15a, the second connection electrode 15b extends from the second excitation electrode 14b to a corner portion of the piezoelectric resonator element 11 in the negative X-axis direction and the negative Z-axis direction, and is electrically connected to an external location outside the piezoelectric resonator 10. Specifically, one end portion of the second connection electrode 15b is connected to the second excitation electrode 14b, and the other end portion is connected to the corner portion of the piezoelectric resonator element 11. The corner portion is exposed from the holding layer 12b. The second excitation electrode 14b is electrically connected to an external location via the second connection electrode 15b located in the area where the corner portion is exposed. In the example illustrated in FIG. 2, each of the first connection electrode 15a and the second connection electrode 15b is electrically connected to an electrode of the buffer 40 described later via an anisotropic conductive paste 19.

The holding layer 12a corresponds to one of a pair of holders that house the vibration portion 16 of the piezoelectric resonator element 11. The holding layer 12a has a depression 18a in a location where the depression 18a overlaps the vibration portion 16 of the piezoelectric resonator element 11 in plan view of the X-Z plane. The depression 18a is open toward the first major face 11a of the piezoelectric resonator element 11. When the piezoelectric resonator element 11 and the holding layer 12a are joined together, the vibration portion 16 and the bottom wall portion of the depression 18a are spaced apart from each other to define therebetween a vibration space for the vibration portion 16 to vibrate. The lateral wall portion of the depression 18a in the holding layer 12a is joined to the first major face 11a in the peripheral edge portion 17 of the piezoelectric resonator element 11. The first excitation electrode 14a is sealed in the vibration space. As with the holding layer 12a, the holding layer 12b corresponds to one of the pair of holders that house the vibration portion 16 of the piezoelectric resonator element 11. The holding layer 12b is positioned to face the holding layer 12a with the piezoelectric resonator element 11 therebetween. The holding layer 12b has a depression 18b in a location where the depression 18b overlaps the vibration portion 16 of the piezoelectric resonator element 11 in plan view of the X-Z plane. The depression 18b is open toward the second major face 11b of the piezoelectric resonator element 11. When the piezoelectric resonator element 11 and the holding layer 12b are joined together, the vibration portion 16 and the bottom wall portion of the depression 18b are spaced apart from each other to define therebetween a vibration space for the vibration portion 16 to vibrate. The lateral wall portion of the depression 18b in the holding layer 12b is joined to the second major face 11b in the peripheral edge portion 17 of the piezoelectric resonator element 11. The second excitation electrode 14b is sealed in the vibration space. The shape of the holding layer 12a and the holding layer 12b is not particularly limited as long as the shape allows the excitation of the vibration portion 16. For example, if the piezoelectric resonator element has an inverted mesa shape, the holding layer may be in the shape of a flat plate. Alternatively, the holding layer 12a and the holding layer 12b may be box-shaped, with cutouts provided at their respective corner portions that contact the first connection electrode 15a and the second connection electrode 15b.

The lower housing 20 is disposed below the piezoelectric resonator 10 and, together with the upper housing 30, houses the piezoelectric resonator 10 inside. The lower housing 20 is less elastically deformable than the upper housing 30. For example, the lower housing 20 and the upper housing 30 may be made to differ in elastic deformability due to their difference in thickness, material, shape, or other features. According to the first embodiment, the upper housing 30 is made of, for example, SUS430 stainless steel with a thickness of about 0.4 mm, and the lower housing 20 is made of, for example, SUS430 stainless steel with a thickness of about 1 mm. The upper housing 30 and the lower housing 20 are thus made to differ in rigidity.

The lower housing 20 has a lower face portion 21, and an end portion 25. The lower face portion 21 is located in the central part of the lower housing 20 in plan view of the X-Y plane. The end portion 25 is located in the outer peripheral part of the lower face portion 21 in plan view of the X-Y plane.

In plan view of the X-Y plane, the lower face portion 21 has a circular shape. However, the lower face portion 21 does not necessarily need to have a circular shape but may have, for example, a rectangular shape. The lower face portion 21 is in the shape of a flat plate with a uniform thickness T21. The lower face portion 21 does not necessarily need to have the above-mentioned shape but may have, for example, at least one projection formed through ribbing. The presence of such a projection further reduces the elastic deformability of the lower surface portion, in comparison to a configuration in which the lower surface portion is in the shape of a flat plate. The lower face portion 21 may partially have a thin-walled portion or a thick-walled portion.

The end portion 25 is provided annularly at the periphery of the lower face portion 21. The end portion 25 clamps an end portion 35 of the upper housing 30, which will be described later, in the thickness direction by being crimped onto the end portion 35. Specifically, the end portion 25 has a lower end portion 25a, an upper end portion 25b, and a fold portion 25c. The lower end portion 25a connects to the lower face portion 21. The upper end portion 25b is folded back upward from the lower end portion 25a. The fold portion 25c connects the lower end portion 25a and the upper end portion 25b with each other. The lower end portion 25a and the upper end portion 25b overlap each other in the thickness direction. The upper end portion 25b and the lower end portion 25a clamp the end portion 35 of the upper housing 30 therebetween in the thickness direction to thereby fix the end portion 35 in place. The gap between the lower end portion 25a, and the end portion 35 of the upper housing 30 is substantially zero. The lower end portion 25a, and the end portion 35 of the upper housing 30 are thus in contact with each other. The gap between the upper end portion 25b, and the end portion 35 of the upper housing 30 is substantially zero. The upper end portion 25b, and the end portion 35 of the upper housing 30 are thus in contact with each other. The configuration mentioned above, however, is not intended to be limiting. It may suffice that at least the upper end portion of the lower housing, and the end portion of the upper housing be in contact with each other. For example, the upper end portion of the lower housing may be in contact with the end portion of the upper housing, and the lower end portion of the lower housing may be spaced apart from the end portion of the upper housing. For example, although the fold portion 25c is spaced apart from the end portion 35 of the upper housing 30, this is not to intended to be limiting and, alternatively, the fold portion 25c may be in contact with the end portion 35.

The upper housing 30 has an upper face portion 31, a lateral face portion 32, and the end portion 35. The upper face portion 31 extends in a circular shape in plan view of the X-Y plane. The lateral face portion 32 extends in the negative Z-axis direction from the outer periphery of the upper face portion 31. The end portion 35 extends in a direction opposite from the upper face portion 31 from the outer peripheral part at the lower end of the lateral face portion 32. The upper face portion 31 has a protruding portion 31a, a peripheral portion 31b, and an intermediate portion 31c. In plan view of the X-Y plane, the protruding portion 31a is located in the central part of the upper face portion 31, and protrudes in the positive Z-axis direction. The peripheral portion 31b surrounds the protruding portion 31a in the X-Y plane. The intermediate portion 31c connects the protruding portion 31a and the peripheral portion 31b with each other. The peripheral portion 31b has a wiring hole 36.

The protruding portion 31a is disposed in the central part of the upper face portion 31, and is a part of the upper face portion 31 that is spaced farthest from the lower face portion 21. The protruding portion 31a is in the shape of a plate extending in the X-Y plane, and has a circular shape in plan view of the X-Y plane. The protruding portion 31a has a thickness T31a in the Z-axis direction. The protruding portion 31a has a lower face at its negative Z-axis side, and an upper face at its positive Z-axis side. The lower face of the protruding portion 31a is in contact with the piezoelectric resonator 10. The upper face of the protruding portion 31a receives the load to be detected by the load sensor 1. The shape of the protruding portion 31a in plan view of the X-Y plane is not limited to a circular shape but may be changed as appropriate based on factors such as the magnitude or extent of the load.

The peripheral portion 31b is provided annularly around the central part in plan view, and is in the shape of a plate extending in the X-Y plane. The outer side end portion of the peripheral portion 31b connects to the upper end of the lateral face portion 32. The peripheral portion 31b is inclined progressively toward the lower face portion 21, that is, downward with increasing distance from the protruding portion 31a. The peripheral portion 31b has a thickness T31b in the Z-axis direction.

The intermediate portion 31c has a tubular shape that connects the protruding portion 31a and the peripheral portion 31b with each other. The intermediate portion 31c is connected at its upper end portion to the outer end portion of the protruding portion 31a, and connected at its lower end portion to the inner end portion of the peripheral portion 31b. The intermediate portion 31c has a thickness T31c in the radial direction in plan view of the X-Y plane.

The thickness T31a of the protruding portion 31a is less than the thickness T21 of the lower face portion 21. The thickness T31a of the protruding portion 31a is substantially equal to the thickness T31b of the peripheral portion 31b. The thickness T31a of the protruding portion 31a is substantially equal to the thickness T31c of the intermediate portion 31c. Alternatively, however, the thickness T31a of the protruding portion 31a may be greater than the thickness T31b of the peripheral portion 31b. In this case, the lower face of the protruding portion 31a, and the lower face of the peripheral portion 31b may be continuous with each other in the X-Y plane. If the upper housing 30 is to be formed by press working, the intermediate portion 31c undergoes elongation. Accordingly, the thickness T31c of the intermediate portion 31c may be less than the thickness T31a of the protruding portion 31a or the thickness T31b of the peripheral portion 31b.

When h1 denotes the height from the lower housing 20 to the connecting part between the outer peripheral face of the intermediate portion 31c and the upper face of the peripheral portion 31b, the height from the lower housing 20 to the upper face of the protruding portion 31a is equal to h1 plus h2, where h2 is the height from the connecting part between the outer peripheral face of the intermediate portion 31c and the upper face of the peripheral portion 31b to the upper face of the protruding portion 31a. The height h1 is greater than the height h2. The height h2 is greater than the thickness T31a of the protruding portion 31a. Therefore, the distance in the thickness direction between the upper face of the peripheral portion 31b and the lower face portion 21 is less than the distance in the thickness direction between the lower face of the protruding portion 31a and the lower face portion 21.

In plan view of the X-Y plane, the protruding portion 31a has an area greater than the area of the piezoelectric resonator 10 and less than the area of the peripheral portion 31b. For example, the area of the protruding portion 31a is preferably greater than or equal to 10% and less than or equal to 20%, more preferably greater than or equal to 5% and less than or equal to 108, or still more preferably about 5% of the area of the upper face portion 31.

The buffer 40 is disposed between the piezoelectric resonator 10, and the lower face portion 21 of the lower housing 20. The buffer 40 has a lower rigidity than the lower housing 20. The buffer 40 helps to reduce cracking in the piezoelectric resonator 10 that can occur upon application of a large load to the load sensor 1. The piezoelectric resonator 10 is set on the central part of the buffer 40 in plan view. The buffer 40 is, for example, a circuit board. As illustrated in FIG. 2, the buffer 40 is electrically connected to each of the first connection electrode 15a and the second connection electrode 15b of the piezoelectric resonator element 11 via the anisotropic conductive paste 19. The buffer 40 is connected to wiring 41. The wiring 41 is extended from the buffer 40 to an external location through the wiring hole 36. Elements other than the piezoelectric resonator 10, such as a capacitor, a resistor, and an inductor, may be mounted on the buffer 40 that is a circuit board. As the raw material of the buffer 40, a substrate material such as glass or epoxy may be used. The buffer 40 may be an adhesive that bonds the piezoelectric resonator 10 and the lower housing 20 to each other, in which case the adhesive may be epoxy or other materials. In this case, the wiring 41 may be extended from the piezoelectric resonator 10 for electrical connection to an external location through the wiring hole 36, without passing through the adhesive. Although the buffer 40 is made of a substrate material or an adhesive material as described above, this is not intended to be limiting. For example, the buffer 40 may be made of a substrate material and an adhesive material, with the adhesive bonding the piezoelectric resonator 10 and the substrate to each other. Although FIG. 2 illustrates an exemplary configuration in which the buffer 40 is provided, in another configuration, the piezoelectric resonator 10 may be mounted on the lower housing 20 with no buffer 40 provided therebetween.

When the load sensor 1 is subjected to a load acting in the direction of the X-Z plane in which the first major face 11a and the second major face 11b of the piezoelectric resonator element 11 extend, distortion occurs in the vibration portion 16. This causes the vibration characteristics of the piezoelectric resonator 10 to change. The change in vibration characteristics is utilized to detect an external load. The load sensor 1 detects the external load through transmission of the load from the protruding portion 31a to the piezoelectric resonator 10. Since the upper face portion 31 has the protruding portion 31a, the load applied from the top of the load sensor 1 is received by the upper face of the protruding portion 31a, and transmitted to the lower face of the protruding portion 31a. This makes it possible to reduce deflection of the upper housing 30 and load dispersion to thereby improve the detection accuracy of the load sensor 1. The load sensor 1 is configured in such a way that, upon fixing the lower housing 20 and the upper housing 30 to each other by crimping at the end portion 25 and the end portion 35, the upper housing 30 is elastically deformed toward the lower housing 20 to thereby apply a preload to the piezoelectric resonator element 11.

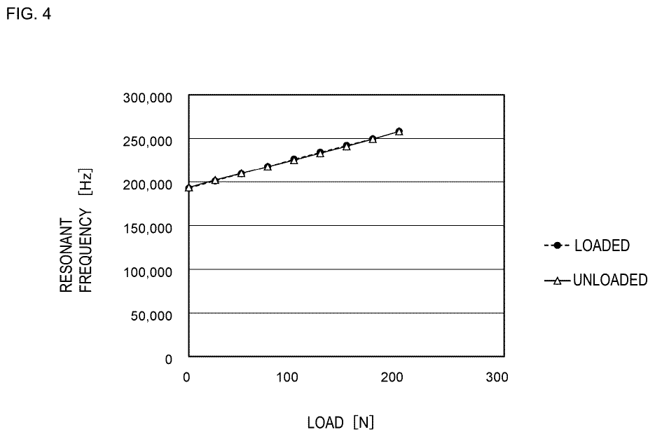

The following describes the results of an experiment conducted on the load sensor 1 according to the first embodiment under loaded and unloaded conditions to investigate the loading characteristics of the load sensor 1. FIG. 4 illustrates the resonant frequency of the piezoelectric resonator 10 with respect to the load applied to the load sensor 1. In FIG. 4, the vertical axis represents the resonant frequency of the piezoelectric resonator 10 [Hz], and the horizontal axis represents the load [N] being applied on the load sensor 1. FIG. 4 plots changes in resonant frequency under a loaded condition in which the load is increased, and changes in resonant frequency under an unloaded condition in which the load is decreased. In FIG. 4, the resonant frequency is accurately proportional to the external force from low load to high load, indicating the presence of high linearity. Further, the transition of the resonant frequency is substantially the same between the loaded and unloaded conditions, indicating the presence of a low hysteresis characteristic. These observations indicate that, through the application of a preload to exclude a low-load region with poor frequency response to load variation, a load sensor with good response has been obtained.

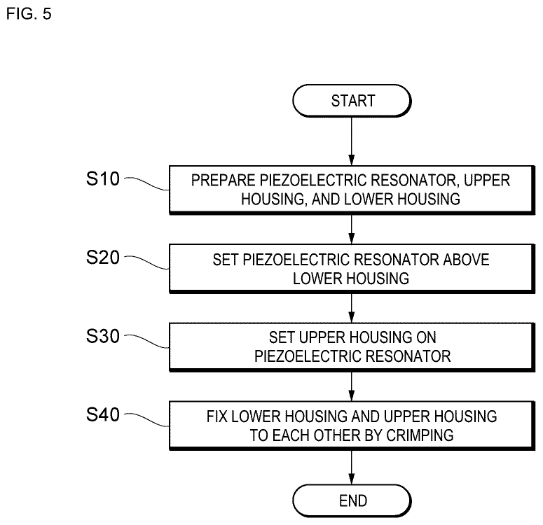

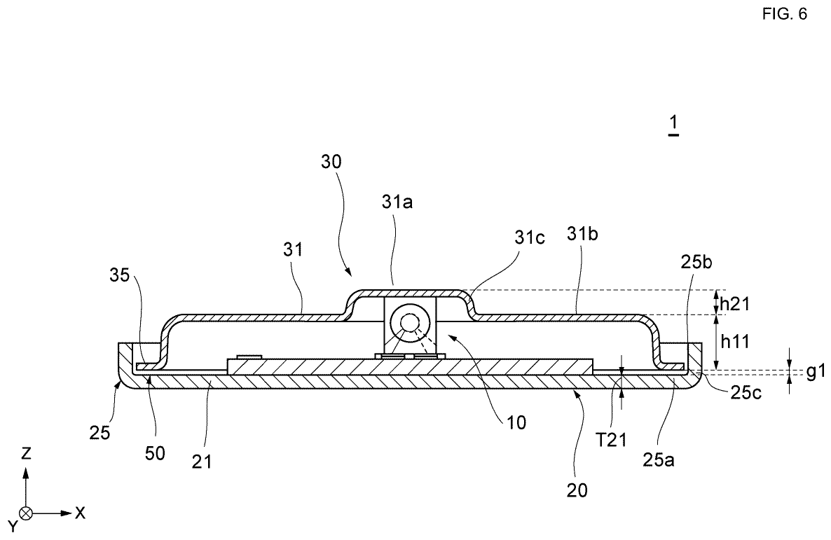

A method for manufacturing the load sensor 1 according to the first embodiment of the present disclosure will now be described with reference to FIGS. 5 and 6. FIG. 5 is a flowchart illustrating a method for manufacturing the load sensor 1 according to the first embodiment of the present disclosure. FIG. 6 is a cross-sectional view of the load sensor according to the first embodiment, illustrating the method for manufacturing the load sensor.

First, the piezoelectric resonator, the upper housing, and the lower housing are prepared (S10).

For example, two kinds of metal plates made of SUS430 stainless steel and having different thicknesses are prepared, and the lower housing 20 and the upper housing 30 are prepared through press-working. As illustrated in FIG. 6, the upper end portion 25b of the lower housing 20 prepared at this step extends in the positive Z-axis direction from the fold portion 25c.

Subsequently, the piezoelectric resonator is set above the lower housing (S20).

The piezoelectric resonator 10 prepared at S10 is mounted on the buffer 40 that serves as a circuit board. Specifically, the piezoelectric resonator element 11, and the pair of holding layers 12a and 12b are disposed as three layers arranged alongside each other in the Y-axis direction, and each of the first connection electrode 15a and the second connection electrode 15b is electrically connected to an electrode pad of the buffer 40 via the anisotropic conductive paste 19. Then, the buffer 40 is set on the lower face portion 21 of the lower housing 20 in such a way that a side of the buffer 40 on which the piezoelectric resonator 10 has been mounted faces up.

Subsequently, the upper housing is set on the piezoelectric resonator (S30).

The upper housing 30 prepared at S10 is set on the piezoelectric resonator 10. Specifically, the upper housing 30 is set in such a way that in plan view of the X-Y plane, the piezoelectric resonator 10, and the protruding portion 31a of the upper housing 30 overlap each other. At this time, as illustrated in FIG. 6, the upper end portion 25b of the lower housing 20 extends in the positive Z-axis direction, and a gap 50 is present between the end portion 35 of the upper housing 30, and the end portion 25 of the lower housing 20. When h11 denotes the height from the lower face of the end portion 35 of the upper housing 30 to the connecting part between the outer peripheral face of the intermediate portion 31c and the upper face of the peripheral portion 31b, the height from the lower face of the end portion 35 of the upper housing 30 to the upper face of the protruding portion 31a is equal to h11 plus h21, where h21 is the height from the connecting part between the outer peripheral face of the intermediate portion 31c and the upper face of the peripheral portion 31b to the upper face of the protruding portion 31a. In this case, when g1 denotes the size of the gap 50 in the thickness direction, the height from the upper face of the lower face portion 21 to the upper face of the peripheral portion 31b is given as g1 +h11, and the height from the upper face of the lower face portion 21 to the upper face of the protruding portion 31a is given as g1+h11+h21. The height h11 is greater than the height h21. The height h21 is greater than the thickness T31a of the protruding portion 31a and the thickness T31b of the peripheral portion Bib. Therefore, the distance in the thickness direction between the upper face of the peripheral portion 31b and the lower face portion 21 is less than the distance in the thickness direction between the lower face of the protruding portion 31a and the lower face portion 21.

The lower housing and the upper housing are fixed to each other by crimping (S40).

As illustrated in FIG. 2, the upper end portion 25b of the lower housing 20 is bent inward into contact with the upper part of the end portion 35. Further, the upper end portion 25b and the lower end portion 25a are pressed to clamp the end portion 35 from above and below. The gap 50, which is used for preload adjustment, is thus decreased, and the end portion 35 of the upper housing 30 and the lower end portion 25a of the lower housing 20 are brought into contact with each other. At this time, the pressing is performed until the size g1 of the gap 50 in the thickness direction becomes substantially zero. This, however, is not intended to be limiting. Alternatively, the pressing may be performed in such a way that a certain amount of the gap 50 is allowed to remain. As the gap 50 decreases in size in the thickness direction, the end portion 35 of the upper housing 30 is displaced downward. Such displacement of the end portion 35 causes elastic deformation of the upper housing 30, which in turn causes a preload to be applied in the thickness direction to the piezoelectric resonator 10. By adjusting the pre-crimping size g1 of the gap 50 in the thickness direction, the preload to be applied to the piezoelectric resonator 10 can be adjusted. Further, if a certain amount of the gap 50 is allowed to remain in the thickness direction after the crimping process, the preload may be adjusted through adjustment of the post-crimping size of the gap 50 in the thickness direction.

The elastic deformation of the upper housing 30 due to the crimping process causes a change in the dimension of the upper housing 30 in the thickness direction. For example, prior to the crimping process, the peripheral portion 31b of the upper housing 30 is substantially horizontal with respect to the lower face portion 21. After the crimping process, the peripheral portion 31b becomes inclined progressively downward with increasing distance from the protruding portion 31a. In this case, the height h11 before the crimping process is less than the height h1 after the crimping process, and h1=h11+g1.

As described above, by fixing the upper housing 30 and the lower housing 20 to each other by crimping, the resulting elastic deformation of the upper housing 30 causes a preload to be applied to the piezoelectric resonator 10.

According to the configuration mentioned above, the preload application makes it possible to exclude a low-load region with poor frequency response to load variation, and consequently provide a load sensor capable of operating in a load region where the load sensor has good response.

In comparison to a configuration in which components such as a screw member and a thrust bearing are provided for preload application, preload application can be performed through the configuration of the upper housing 30 and the lower housing 20. As a result, the load sensor 1 can be reduced in profile.

Crimping is performed on the lower housing 20, which is less elastically deformable than the upper housing 30. This makes it possible to reduce the risk of the crimped portion becoming loose, and consequently reduce the variation with time of the preload applied to the piezoelectric resonator 10.

The presence of the protruding portion 31a makes it possible to directly transmit the load exerted on the load sensor 1 to the piezoelectric resonator 10, and reduce deflection of the upper housing 30 and load dispersion to thereby improve the detection accuracy of the load sensor 1.

The presence of the buffer 40 makes it possible to reduce cracking of the piezoelectric resonator element 11 under applied load. The use of a circuit board as the buffer 40 allows for reduced size of the load sensor 1.

According to the first embodiment, the end portion 25 and the end portion 35 are provided annularly. This configuration allows for isotropic application of a preload to the piezoelectric resonator 10. This, however, is not intended to be limiting. The end portion of the upper housing and the end portion of the lower housing may be provided annularly along only part, rather than the entirety, of the circumference of the corresponding housings. Further, even if the end portion of the upper housing and the end portion of the lower housing are provided annularly along the entire circumference of the corresponding housings, crimping may be performed only on a limited part of the end portions.

Other embodiments will now be described. In each of the embodiments below, matters identical to those according to the first embodiment mentioned above will not be described, and only differences from the first embodiment will be described. Features similar in configuration and function to those of the first embodiment will be designated by reference signs similar to those of the first embodiment and, hence, subsequent detailed descriptions thereof will be omitted. Reference will not be made to operational effects provided by such similar features.

### Second Embodiment

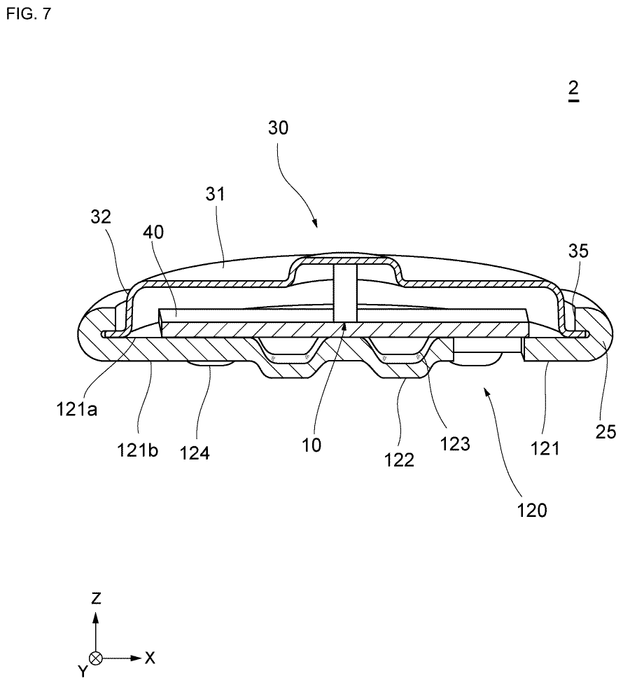

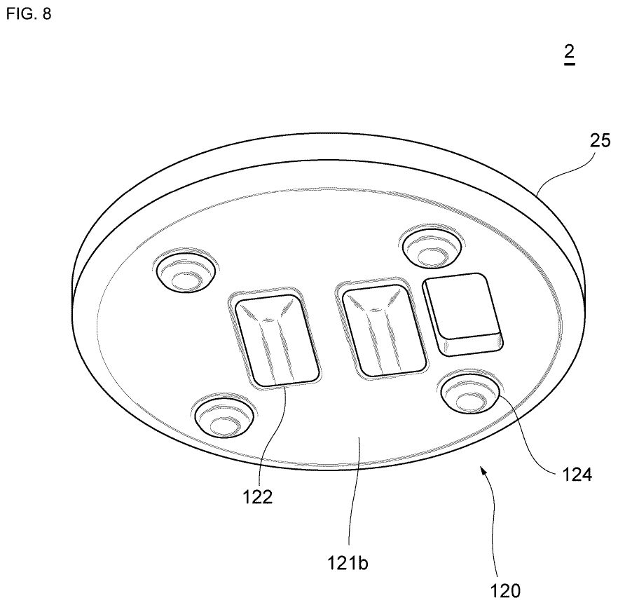

A load sensor 2 according to a second embodiment will now be described with reference to FIGS. 7 and 8. FIG. 7 is a cross-sectional view of the load sensor according to the first embodiment, schematically illustrating the structure of the load sensor. FIG. 8 is a perspective view of the load sensor according to the second embodiment, schematically illustrating the structure of the load sensor.

The second embodiment differs from the first embodiment in the structure of the lower housing 20. Specifically, according to the first embodiment, the lower face portion 21 of the lower housing 20 is in the shape of a flat plate. According to the second embodiment, a lower face portion 121 of a lower housing 120 has, at a lower face 121b located opposite from the upper housing 30, a plurality of projections 122 formed by ribbing. This configuration allows the lower housing 120 to be further reduced in elastic deformability, in comparison to a lower housing whose lower face portion is in the shape of a flat plate. The number of such projections is not limited. It may suffice that at least one such projection be provided. In another example, the projections may be provided at an upper face 121a, which is a face of the lower face portion 121 that faces the upper housing 30. In another example, the projections may be provided at both the upper face 121a and the lower face 121b of the lower face portion 121.

As illustrated in FIG. 7, the upper face 121a, which has no projections 122, has depressions 123 at locations corresponding to the projections 122. This allows the manufacturing process to be simplified by, for example, simultaneously forming the projections 122 and the depressions 123 through press-working.

According to the second embodiment, the projections 122 and the depressions 123 are formed integrally as described above. This, however, is not intended to be limiting. That is, the area corresponding to the back of each projection 122 may be formed flat with no depression 123.

The lower face 121b is provided with fixation portions 124, which serve as the feet of the load sensor 2. If the lower face 121b is provided with the projections 122 and the fixation portions 124, the fixation portions 124 have a dimension in the thickness direction greater than or equal to the dimension in the thickness direction of the projections 122. As seen in plan view of the X-Y plane of the lower face 121b, the fixation portions 124 are located closer to the outer periphery than are the projections 122. Upon mounting the load sensor 2 on an external substrate, the fixation portions 124 come into contact with the external substrate. This makes it possible to stabilize the orientation of the load sensor 2, and consequently enhance the reliability of sensing. Although four fixation portions 124 are provided according to the second embodiment, the number of fixation portions 124 is not limited to four. Preferably, three or more fixation portions 124 are provided. The number or shape of the fixation portions may be changed as appropriate as long as such fixation portions can serve as feet.

### Third Embodiment

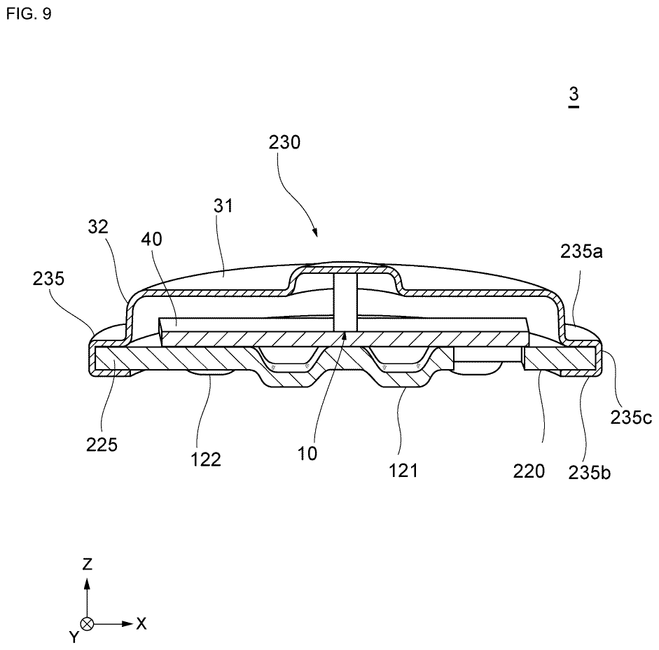

The structure of a load sensor 3 according to a third embodiment will now be described with reference to FIG. 9. FIG. 9 is a cross-sectional view of the load sensor according to the third embodiment, schematically illustrating the structure of the load sensor.

The third embodiment differs from the first embodiment in how crimping is performed. Specifically, according to the first embodiment, the end portion 25 of the lower housing 20 is crimped onto the upper housing 30. In contrast, according to the third embodiment, an end portion 235 of an upper housing 230 is crimped onto a lower housing 220. According to the third embodiment, the end portion 235 of the upper housing 230 has an upper end portion 235a, a lower end portion 235b, and a fold portion 235c. The upper end portion 235a connects to the lateral face portion 32. The lower end portion 235b is folded back downward from the upper end portion 235a. The fold portion 235c connects the upper end portion 235a and the lower end portion 235b with each other. An end portion 225 of the lower housing 220 is clamped in the thickness direction by the upper end portion 235a and the lower end portion 235b. According to the configuration mentioned above, crimping is performed on the upper housing 230, which is more elastically deformable than the lower housing 220. This makes it possible to provide the load sensor 3 with improved working accuracy relative to the first embodiment. If the upper housing 230 is thin, the upper housing 230 can be crimped easily.

Some or all of the embodiments of the present disclosure will now be described as supplementary notes. It is to be noted that the supplementary notes below are not intended to be limiting of the present disclosure.

<1> As described above, according to an aspect of the present disclosure, there is provided a load sensor that detects a load applied in a thickness direction. The load sensor includes: an upper housing having an upper face portion, and a lateral face portion that extends in the thickness direction from an outer periphery of the upper face portion; a lower housing having a lower face portion that faces the upper face portion in the thickness direction, the lower housing being less elastically deformable than the upper housing; and a piezoelectric resonator housed in a space between the upper housing and the lower housing, the piezoelectric resonator including a piezoelectric substrate between the upper face portion and the lower face portion, and a pair of excitation electrodes on opposite major faces of the piezoelectric substrate, wherein the pair of excitation electrodes extend in the thickness direction, and wherein an end portion of the upper housing and an end portion of the lower housing are fixed to each other with a crimp such that the upper housing is elastically deformed and causes a preload to be applied by the upper housing to the piezoelectric resonator in the thickness direction.

According to the aspect mentioned above, the upper housing and the lower housing are fixed to each other by crimping. The resulting elastic deformation of the upper housing allows a preload to be applied to the piezoelectric resonator. The preloading makes it possible to provide a load sensor with good loading characteristics. Further, the aspect mentioned above makes it possible to provide a load sensor with a reduced profile and reduced long-term fluctuations, in comparison to conventional load sensors that include an externally provided feature for preload application.

<2> According to an aspect, there is provided the load sensor according to <1>, in which the end portion of the upper housing is clamped in the thickness direction by the end portion of the lower housing.

<3> According to an aspect, there is provided the load sensor according to <1>, in which the end portion of the lower housing is clamped in the thickness direction by the end portion of the upper housing.

<4> According to an aspect, there is provided the load sensor according to any one of <1> to <3>, in which: the upper face portion has a protruding portion; the protruding portion is located in a central part of the upper face portion in a plan view of the load sensor and protrudes in a direction opposite from the lower face portion; and the piezoelectric resonator is between the protruding portion and the lower face portion.

According to the aspect mentioned above, the protruding portion receives the applied load. This makes it possible to reduce deflection of the upper housing and load dispersion to thereby improve the detection accuracy of the load sensor.

<5> According to an aspect, there is provided the load sensor according to any one of <1> to <4>, further including a buffer between the lower face portion and the piezoelectric resonator. The buffer is more elastically deformable than the lower housing.

According to the aspect mentioned above, the piezoelectric resonator 10 can be made less susceptible to cracking under load upon application of a large load to the load sensor 1.

<6> According to an aspect, there is provided the load sensor according to <5>, in which the buffer is a circuit board electrically connected to the piezoelectric resonator.

<7> According to an aspect, there is provided the load sensor according to any one of <1> to <6>, in which the lower face portion has at least one first projection.

According to the aspect mentioned above, the lower face portion can be improved in strength.

<8> According to an aspect, there is provided the load sensor according to <7>, in which: the first projection of the lower face portion projects in a direction opposite from the upper face portion; the lower face portion further has a second projection that projects in the direction opposite from the upper face portion; and the second projection projects by an amount greater than or equal to an amount by which the first projection projects from the lower face portion, and in the plan view of the load sensor, the second projection is between the first projection and an end portion of the lower face portion.

According to the aspect mentioned above, the load sensor can be stabilized in orientation. This allows for improved reliability of sensing.

<9> According to an aspect, there is provided the load sensor according to any one of <1> to <8>, in which the piezoelectric resonator is a crystal resonator.

<10> According to another aspect of the present disclosure, there is provided a method for manufacturing a load sensor that detects a load in a thickness direction, the method including: setting a piezoelectric resonator above a lower housing having a lower face portion, the piezoelectric resonator including a piezoelectric substrate, and a pair of excitation electrodes on opposite major faces of the piezoelectric substrate; setting an upper housing on the piezoelectric resonator so as to cause the upper housing to be supported on the piezoelectric resonator and provide a preload adjustment gap between an end portion of the upper housing and an end portion of the lower housing, the upper housing having an upper face portion that faces the lower face portion in the thickness direction, and a lateral face portion that extends in the thickness direction from an outer periphery of the upper face portion, and the lower housing being less elastically deformable than the upper housing; and crimping the end portion of the upper housing and the end portion of the lower housing to each other while decreasing the preload adjustment gap and causing the upper housing to undergo elastic deformation and apply a preload to the piezoelectric resonator in the thickness direction.

According to the aspect mentioned above, a method for manufacturing a load sensor having good loading characteristics due to preloading can be provided.

The embodiments described above are intended to facilitate understanding of the present disclosure, and not to be construed as limiting of the present disclosure. Various changes/modifications may be made to the present disclosure without departing from its spirit and scope, and the present disclosure encompasses equivalents thereof. That is, the embodiments with suitable design variations made thereto by those skilled in the art also fall within the scope of the present disclosure as long as the resulting embodiments include the characteristic features of the present disclosure. For example, individual elements included in the embodiments, and their associated arrangements, materials, conditions, shapes, sizes, or other specific details are not limited to those illustrated but may be changed as appropriate. Elements in individual embodiments can be combined as long as technically feasible, and any such combination that includes the characteristic features of the present disclosure also falls within the scope of the present disclosure.

### REFERENCE SIGNS LIST

1 load sensor
10 piezoelectric resonator
11 piezoelectric resonator element
20 lower housing
30 upper housing
40 buffer
50 gap

1. A load sensor that detects a load applied in a thickness direction, the load sensor comprising:
an upper housing having
an upper face portion, and
a lateral face portion that extends in the thickness direction from an outer periphery of the upper face portion;
a lower housing having a lower face portion that faces the upper face portion in the thickness direction, the lower housing being less elastically deformable than the upper housing; and
a piezoelectric resonator housed in a space between the upper housing and the lower housing, the piezoelectric resonator including
a piezoelectric substrate between the upper face portion and the lower face portion, and
a pair of excitation electrodes on opposite major faces of the piezoelectric substrate,
wherein the pair of excitation electrodes extend in the thickness direction, and
wherein an end portion of the upper housing and an end portion of the lower housing are fixed to each other with a crimp such that the upper housing is elastically deformed and causes a preload to be applied by the upper housing to the piezoelectric resonator in the thickness direction.

2. The load sensor according to claim 1, wherein the end portion of the upper housing is clamped in the thickness direction by the end portion of the lower housing.

3. The load sensor according to claim 1, wherein the end portion of the lower housing is clamped in the thickness direction by the end portion of the upper housing.

4. The load sensor according to claim 1,
wherein the upper face portion has a protruding portion,
wherein the protruding portion is located in a central part of the upper face portion in a plan view of the load sensor and protrudes in a direction opposite from the lower face portion, and
wherein the piezoelectric resonator is between the protruding portion and the lower face portion.

5. The load sensor according to claim 1, further comprising a buffer between the lower face portion and the piezoelectric resonator, the buffer being more elastically deformable than the lower housing.

6. The load sensor according to claim 5, wherein the buffer is a circuit board electrically connected to the piezoelectric resonator.

7. The load sensor according to claim 1, wherein the lower face portion has at least one first projection.

8. The load sensor according to claim 7,
wherein the first projection projects from the lower face portion in a direction opposite from the upper face portion,
wherein the lower face portion further has a second projection that projects in the direction opposite from the upper face portion, and
wherein the second projection projects by an amount greater than or equal to an amount by which the first projection projects from the lower face portion, and in a plan view of the load sensor, the second projection is between the first projection and an end portion of the lower face portion.

9. The load sensor according to claim 1, wherein the piezoelectric resonator is a crystal resonator.

10. A method for manufacturing a load sensor that detects a load in a thickness direction, the method comprising:
setting a piezoelectric resonator above a lower housing having a lower face portion, the piezoelectric resonator including a piezoelectric substrate, and a pair of excitation electrodes on opposite major faces of the piezoelectric substrate;
setting an upper housing on the piezoelectric resonator so as to cause the upper housing to be supported on the piezoelectric resonator and provide a preload adjustment gap between an end portion of the upper housing and an end portion of the lower housing, the upper housing having an upper face portion that faces the lower face portion in the thickness direction, and a lateral face portion that extends in the thickness direction from an outer periphery of the upper face portion, and the lower housing being less elastically deformable than the upper housing; and
crimping the end portion of the upper housing and the end portion of the lower housing to each other while decreasing the preload adjustment gap and causing the upper housing to undergo elastic deformation and apply a preload to the piezoelectric resonator in the thickness direction.

11. The method for manufacturing a load sensor according to claim 10, wherein the end portion of the upper housing is crimped in the thickness direction by the end portion of the lower housing.

12. The method for manufacturing a load sensor according to claim 10, wherein the end portion of the lower housing is crimped in the thickness direction by the end portion of the upper housing.

13. The method for manufacturing a load sensor according to claim 10,
wherein the upper face portion has a protruding portion,
wherein the protruding portion is located in a central part of the upper face portion in a plan view of the load sensor and protrudes in a direction opposite from the lower face portion, and
wherein the piezoelectric resonator is between the protruding portion and the lower face portion.

14. The method for manufacturing a load sensor according to claim 10, the method further comprising placing a buffer between the lower face portion and the piezoelectric resonator, the buffer being more elastically deformable than the lower housing.

15. The method for manufacturing a load sensor according to claim 14, wherein the buffer is a circuit board electrically connected to the piezoelectric resonator.

16. The method for manufacturing a load sensor according to claim 10, further comprising forming at least one first projection in the lower face portion.

17. The method for manufacturing a load sensor according to claim 16,
wherein the first projection is formed so as to project from the lower face portion in a direction opposite from the upper face portion,
wherein the method further comprises forming a second projection in the lower face portion, the second projection projecting in the direction opposite from the upper face portion, and
wherein the second projection projects by an amount greater than or equal to an amount by which the first projection projects from the lower face portion, and in a plan view of the load sensor, the second projection is between the first projection and an end portion of the lower face portion.

18. The method for manufacturing a load sensor according to claim 10, wherein the piezoelectric resonator is a crystal resonator.
